(19) United States
(12) Patent Application Publication
(10) Pub. No.: US 2014/0133080 A1
(43) Pub. Date: May 15, 2014

(54) DETACHABLE ELECTRONIC DEVICE AND CONNECTION APPARATUS USABLE WITH THE SAME

(71) Applicant: Samsung Electronics Co., Ltd., Suwon-si (KR)

(72) Inventors: Sung-ho HWANG, Suwon-si (KR); June-young HUR, Suwon-si (KR); Ki-young KWON, Yongin-si (KR)

(73) Assignee: Samsung Electronics Co., Ltd., Suwon-si (KR)

(21) Appl. No.: 14/074,856

(22) Filed: Nov. 8, 2013

Related U.S. Application Data
(60) Provisional application No. 61/726,811, filed on Nov. 15, 2012.

(30) Foreign Application Priority Data
Nov. 23, 2012 (KR) 10-2012-0133884

(51) Int. Cl. G06F 1/16; H05K 7/14

(52) U.S. Cl. CPC G06F 1/1633; H05K 7/14
USPC 361/679.17

(57) ABSTRACT

A detachable electronic device includes a connection apparatus disposed in one end of a peripheral apparatus to which a tablet computer is detachably mounted, the connection apparatus includes a base disposed in the peripheral apparatus, a mounting groove that is formed in the base and in which one end of the tablet computer is inserted, a hook disposed on a bottom surface of the mounting groove to move parallel to the mounting groove, and a pressure member to push the hook in a direction, and the tablet computer includes an inserting groove formed in the one end of the tablet computer and in which the hook can be inserted, a catch projection formed at a side surface of the inserting groove and which engages the hook, and a pushing projection disposed opposite to the catch projection inside the inserting groove.

### CROSS-REFERENCE TO RELATED APPLICATIONS

This application claims the benefit under 35 U.S.C. §119(e) from U.S. provisional application No. 61/726,811, filed Nov. 15, 2012, in the United States Patent & Trademark Office, and claims the benefit under 35 U.S.C. §119(a) from Korean Patent Application No. 10-2012-0133884, filed Nov. 23, 2012, in the Korean Intellectual Property Office, the disclosures of which are incorporated herein by reference in their entirety.

### BACKGROUND OF THE INVENTION

1. Field of the Invention

The present general inventive concept relates to a detachable electronic device including a tablet computer that can be detached from a peripheral device. More particularly, the present general inventive concept relates to a detachable electronic device with a connection apparatus that is disposed in a peripheral device and allows a tablet computer to be easily mounted to and separated from the peripheral device and a connection apparatus usable with the detachable electronic device.

2. Description of the Related Art

Until now notebook computers have been used frequently as portable computers. Notebook computers are convenient since data can be input by using a keyboard.

However, recently, tablet computers that have good mobility and use touch input have been used widely as portable computers. However, since a tablet computer is formed to enter data only by touch, usability such as the input of large amounts of data is inferior to conventional notebook computers which include a keyboard. Accordingly, a connection apparatus is needed that allows a keyboard that can extend the usability of the tablet computer to easily be mounted to and separated from the tablet computer.

Also, since a tablet computer cannot be stood up at a certain angle on the ground, a separate stand to fix the tablet computer is needed. Accordingly, a connection apparatus that allows the tablet computer to easily be mounted to and separated from the stand is required.

Also, since a tablet computer generally has small battery capacity, it may need to be supplied with electrical power by using an auxiliary battery pack that can be connected to the tablet computer. In this case, a connection apparatus that allows the tablet computer and the auxiliary battery pack to easily be connected to and separated from each other is needed.

Therefore, in order to improve the usability of a tablet computer, a connection apparatus that allows the tablet computer to be mounted to and separated from a peripheral device such as the keyboard is necessary, as well as a stand, an auxiliary battery pack, etc.

### SUMMARY OF THE INVENTION

The present general inventive concept has been developed in order to overcome the above drawbacks and other problems associated with the conventional arrangement. Features and utilities of the present general inventive concept relate to a connection apparatus of a detachable electronic device including a tablet computer and a peripheral apparatus that allows the tablet computer to easily be mounted to and separated from the peripheral apparatus.

Additional features and utilities of the present general inventive concept will be set forth in part in the description which follows and, in part, will be obvious from the description, or may be learned by practice of the general inventive concept.

Exemplary embodiments of the present general inventive concept provide a detachable electronic device which may include a connection apparatus that is disposed in one end of a peripheral apparatus and to which a tablet computer is detachably mounted, wherein the connection apparatus may include a base disposed in the peripheral apparatus, a mounting groove that is formed in the base and in which one end of the tablet computer is inserted, a hook disposed on a bottom surface of the mounting groove and adapted to move parallel to the mounting groove, and a pressure member to push the hook in a first direction, and the tablet computer may include an inserting groove that is formed in the one end of the tablet computer and in which the hook can be inserted, a catch projection that is formed at a side surface of the inserting groove and which engages with the hook, and a pushing projection disposed opposite to the catch projection inside the inserting groove.

A distance between the pushing projection and a head of the hook may be larger than a distance traveled by the hook to engage with the catch projection.

When the hook moves more than the distance between the hook and the catch projection in a second direction opposite to the first direction, the hook may push the pushing projection away from the mounting groove.

The connection apparatus may include a moving member on which the hook is formed, the moving member being disposed to move with respect to the base, a slope projection formed on the moving member, a release button that is disposed in the base to move perpendicular to the moving member and comprises a pressure protrusion to push on the slope projection, and an elastic member disposed between the release button and the moving member, and wherein when the release button is pressed, the pressure protrusion of the release button may push on the slope projection of the moving member, and thus the moving member may be moved so that the hook pushes the pushing projection away from the mounting groove.

The connection apparatus may include a protection protrusion to surround the hook formed on the bottom surface of the mounting groove.

The base may be rotatably disposed in the peripheral apparatus.

The connection apparatus may include a connector to electrically connect the tablet computer and the peripheral apparatus disposed on the bottom surface of the mounting groove.

The connector may include a plurality of pogo pins.

The connection apparatus may include an auxiliary pressure member formed on the bottom surface of the mounting groove to push the tablet computer away from the mounting groove.

The peripheral apparatus may include at least one of a keyboard unit, a stand, and an auxiliary battery unit.

Exemplary embodiments of the present general inventive concept provide a connection apparatus to connect a peripheral apparatus and a tablet computer which may include a base rotatably disposed in one end of the peripheral apparatus, a mounting groove that is formed in the base and in which one end of the tablet computer is inserted, a moving member disposed below a bottom surface of the mounting groove to move parallel to the mounting groove, a hook that is formed on a top surface of the moving member and projects inside the mounting groove through a through hole of the mounting groove, a pressure member with one end fixed to the moving member and the other end fixed to the base to push the moving member in a predetermined direction, a slope projection formed on a top surface of the moving member, a release button that is disposed in the base to move perpendicular to the moving member and comprises a pressure protrusion to push on the slope projection, and an elastic member disposed between the release button and the moving member, wherein when the release button is pressed, the pressure protrusion of the release button may push on the slope projection of the moving member, and thus the moving member may be moved in a direction opposite to the predetermined direction in which the pressure member pushes the moving member.

When a force applied to the release button is removed, the moving member may be restored to an original position by the pressure member.

The base may include a upper base and a lower base, the moving member may be disposed to move between the upper base and the lower base, and the upper base may include a button hole in which the release button is disposed.

A protection protrusion to surround the hook may be formed on the bottom surface of the mounting groove.

When the release button is pressed, the hook may be formed to push the tablet computer away from the mounting groove.

The connection apparatus may include rotation shafts disposed opposite ends of the base.

A connector to electrically connect the tablet computer and the peripheral apparatus may be disposed in the bottom surface of the mounting groove.

The connector may include a plurality of pogo pins.

At least one auxiliary pressure member to push the tablet computer away from the mounting groove may be disposed in the bottom surface of the mounting groove.

According to an exemplary embodiment of the present general inventive concept, a connection apparatus usable with an electronic device may include a base to be connectable to a peripheral apparatus and a tablet computer, a moving member movably disposed in the base to hold or release one of the peripheral apparatus and the tablet computer, and a separation member movably disposed in the base to move the moving member according to an association of a release member of the separation member and a slope projection of the moving member.

The separation member may include a pressurizing member configured to push the tablet computer away from the base when the moving member is moved to release one of the peripheral apparatus and the tablet computer.

The base may include an upper base fixedly connected to the peripheral device, and a lower base detachably attached to the tablet computer.

The moving member may include a hook to hold or release the tablet computer.

The moving member may comprise a pressure member to push the moving member in a direction to hold the tablet computer, wherein the association of the release member of the separation member and the slope projection of the moving member moves the moving member in a direction to release the tablet computer.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a perspective view illustrating a tablet computer prior to being connected to a keyboard unit corresponding to a peripheral apparatus in a detachable electronic device according to an exemplary embodiment of the present general inventive concept;

FIG. 2 is a perspective view illustrating the tablet computer connected to a connection apparatus of the keyboard unit in the detachable electronic device of FIG. 1;

FIG. 3 is a perspective view illustrating the tablet computer covering the keyboard unit in the detachable electronic device of FIG. 2;

FIG. 4 is a perspective view illustrating a connection apparatus used in a detachable electronic device according to an exemplary embodiment of the present general inventive concept;

FIG. 5 is an exploded perspective view illustrating the connection apparatus of FIG. 4;

FIG. 6A is a sectional view schematically illustrating relationship between a release button, a moving member, and hooks before the release button is pressed according to an exemplary embodiment of the present general inventive concept;

FIG. 6B is a sectional view schematically illustrating a relationship between a release button, a moving member, and hooks after the release button is pressed according to an exemplary embodiment of the present general inventive concept;

FIG. 7A is a partial sectional view illustrating a hook of a connection apparatus being inserted into an inserting groove of a tablet computer according to an exemplary embodiment of the present general inventive concept;

FIG. 7B is a partial sectional view illustrating a hook of a connection apparatus completely inserted in an inserting groove of a tablet computer, thereby engaging a catch projection according to an exemplary embodiment of the present general inventive concept;

FIG. 7C is a partial sectional view illustrating a pushing projection of an inserting groove of a tablet computer being pushed by a hook of a connection apparatus when a release button is pressed according to an exemplary embodiment of the present general inventive concept;

FIG. 8 is a partial sectional view illustrating another example of a pushing projection formed in an inserting groove of a tablet computer according to an exemplary embodiment of the present general inventive concept;

FIG. 9A is a partial sectional view schematically illustrating a connection relationship between hooks and a connector when a tablet computer is mounted to a connection apparatus according to an exemplary embodiment of the present general inventive concept;

FIG. 9B is a partial sectional view illustrating the tablet computer upwardly receiving force by the hooks and connector when the hooks are moved by a release button in the state of FIG. 9A;

FIG. 10 is a perspective view illustrating a connection apparatus usable with a detachable electronic device according to an exemplary embodiment of the present general inventive concept;

FIG. 11 is a sectional view illustrating an example of an auxiliary pressure member disposed in the connection apparatus of FIG. 10; and

FIG. 12 is a sectional view illustrating another example of an auxiliary pressure member disposed in the connection apparatus of FIG. 10.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

The matters defined herein, such as a detailed construction and elements thereof, are provided to assist in a comprehensive understanding of this description. Thus, it is apparent that exemplary embodiments may be carried out without those defined matters. Also, well-known functions or constructions are omitted to provide a clear and concise description of exemplary embodiments. Further, dimensions of various elements in the accompanying drawings may be arbitrarily increased or decreased to assist in a comprehensive understanding.

Furthermore, for the purposes of the exemplary embodiments described herein, directional terms such as “upwards” and “downwards” are used relative to the illustrations in the Figures, except where otherwise indicated.

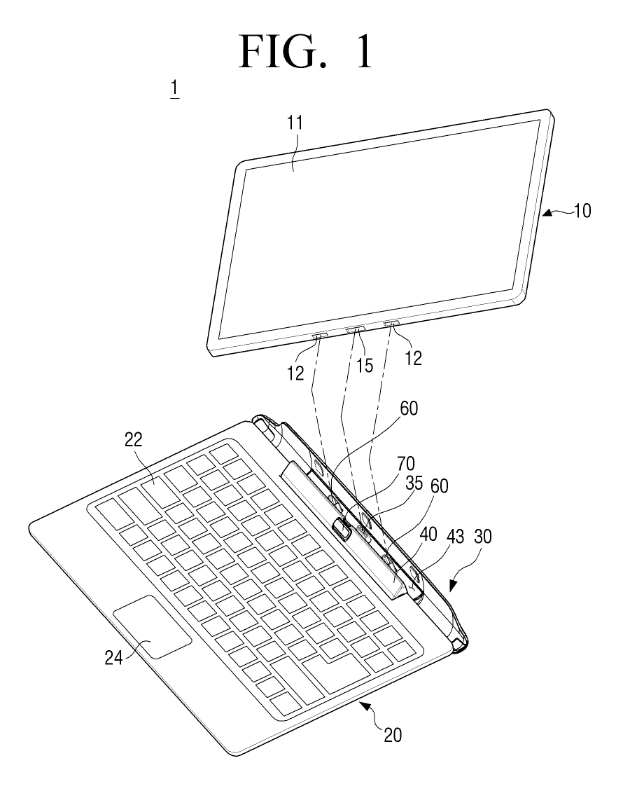

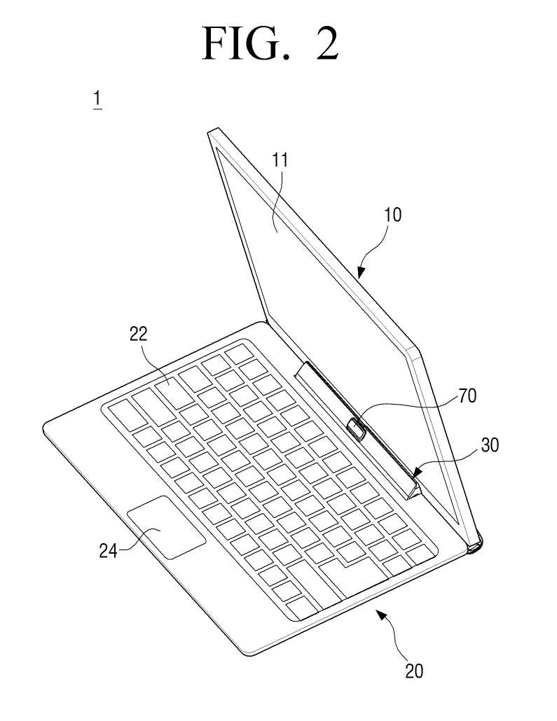

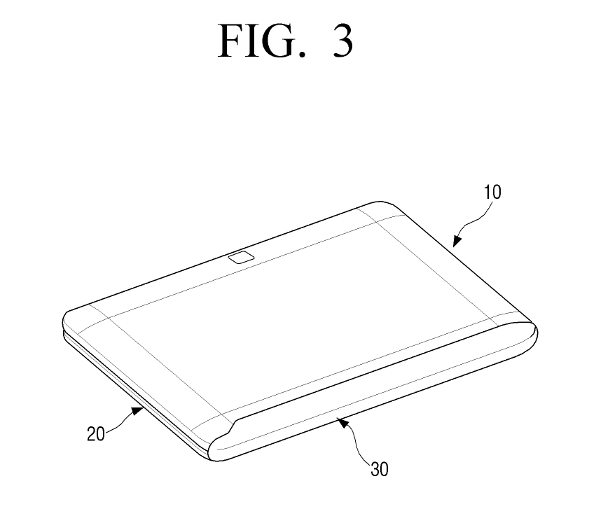

FIG. 1 is a perspective view illustrating a tablet computer 10 prior to being connected to a connection apparatus 30 of a peripheral apparatus 20 corresponding to a keyboard unit in a detachable electronic device 1 according to an exemplary embodiment of the present general inventive concept, and FIG. 2 is a perspective view illustrating the tablet computer 10 is connected to the connection apparatus 30 of the keyboard unit 20 in the detachable electronic device 1 of FIG. 1. FIG. 3 is a perspective view illustrating the tablet computer 10 covering the keyboard unit 20 in the detachable electronic device 1 of FIG. 2.

Referring to FIGS. 1, 2 and 3, the detachable electronic device 1 according to an exemplary embodiment of the present general inventive concept includes the tablet computer 10, the peripheral apparatus 20 that may be coupled to or separated from the tablet computer 10 depending on user's needs, and the connection apparatus 30 that connects the tablet computer 10 and the peripheral apparatus 20.

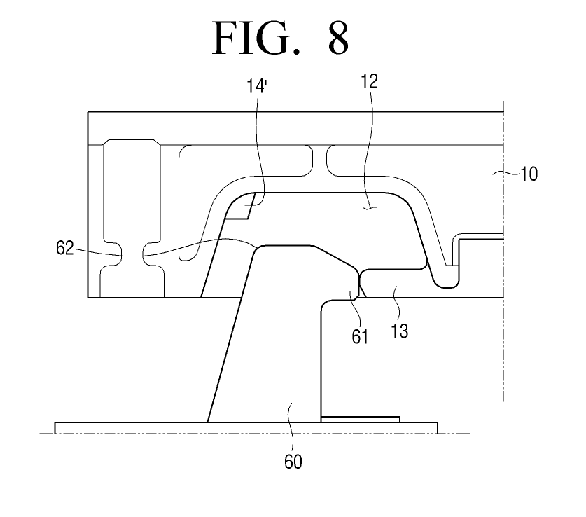

The tablet computer 10 may be formed in the shape of an approximately rectangular plate, and a touch screen 11 is provided on a front surface of the tablet computer 10. As illustrated in FIG. 1, inserting grooves 12 and a connector groove 15 are provided on an end of the tablet computer 10, that is, on one of four side surfaces of the tablet computer 10. The inserting grooves 12 are formed so that hooks 60 of the connection apparatus 30 are inserted into and coupled to the inserting grooves 12, and the number of the inserting grooves 12 corresponds to the number of the hooks 60. In the present exemplary embodiment of the present general inventive concept, since the connection apparatus 30 is provided with two hooks 60, two inserting grooves 12 are formed in the tablet computer 10. The connector groove 15 is formed between the two inserting grooves 12, and a connector 35 of the connection apparatus 30 is inserted in the connector groove 15. A plurality of contact points 16 (see FIGS. 9A and 9B) is provided on a bottom surface of the connector groove 15.

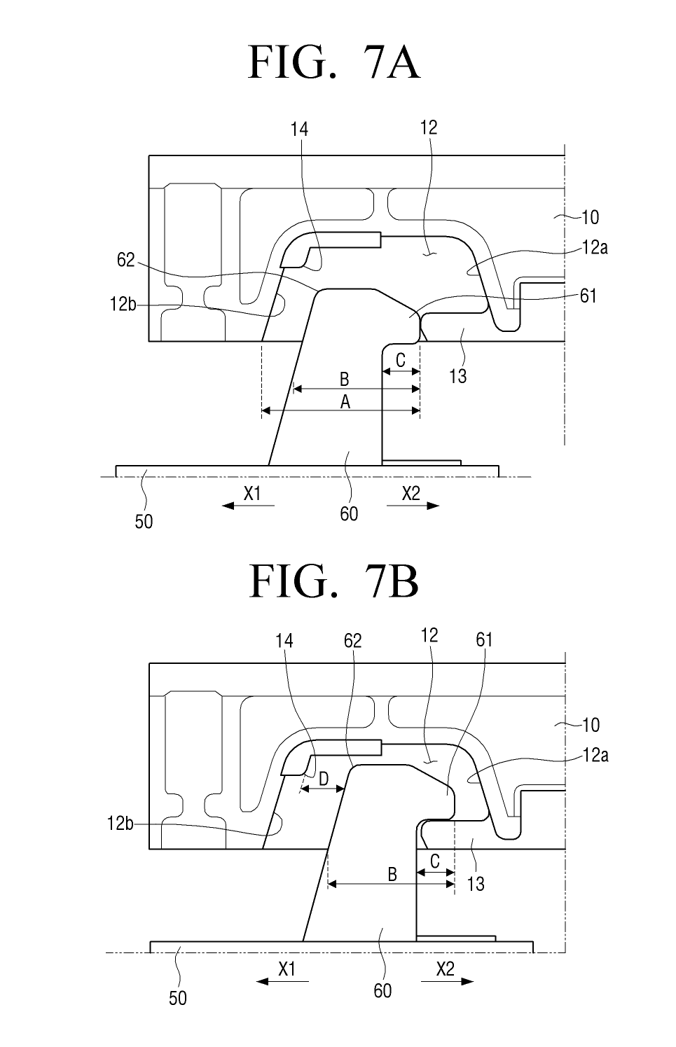

FIG. 7A is a partial sectional view illustrating the hook 60 of the connection apparatus 30 being inserted into the inserting groove 12 of the tablet computer 10 according to an exemplary embodiment of the present general inventive concept. FIG. 7B is a partial sectional view illustrating the hook 60 of the connection apparatus 30 completely inserted in the inserting groove 12 of the tablet computer 10, thereby engaging a catch projection 13 according to an exemplary embodiment of the present general inventive concept. FIG. 7C is a partial sectional view illustrating a pushing projection 14 of the inserting groove 12 of the tablet computer 10 being pushed by the hook 60 of the connection apparatus 30 when a release button 70 is pressed according to an exemplary embodiment of the present general inventive concept.

Referring to FIG. 7A, the inserting groove 12 is formed to have a predetermined depth in a side surface of the tablet computer 10, and the catch projection 13 is formed to protrude a certain height from a side surface 12a of the inserting groove 12. The catch projection 13 interferes with a nose of the hook 60, thereby preventing the hook 60 from coming out of the inserting groove 12. The pushing projection 14 may be formed on another side surface 12b of the inserting groove 12, that is, on a side surface 12b of the inserting groove 12 opposite to the side surface 12a of the inserting groove 12 on which the catch projection 13 is formed. The pushing projection 14 may be formed in a shape that can interfere with a head 62 of the hook 60 and thus push the tablet computer 10 in an upward direction. In FIGS. 7A, 7B, and 7C, the pushing projection 14 is formed to have an arc-shaped cross-section. However, the shape of the pushing projection 14 is not limited to this shape. The pushing projection 14 may be formed in various shapes as long as it can interfere with the head 62 of the hook 60 and generate a force to push the tablet computer 10 in the upward direction.

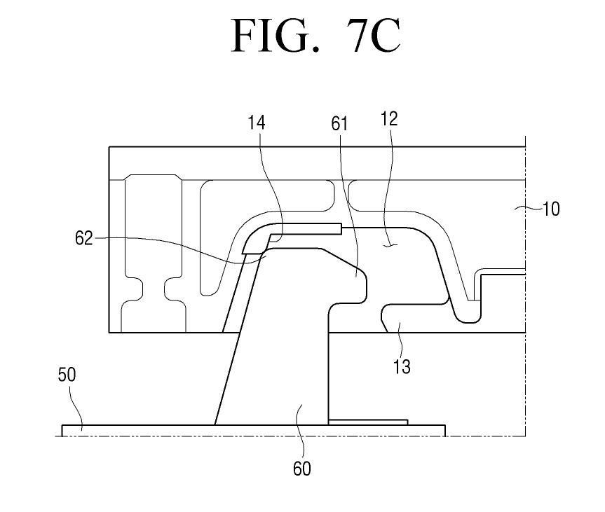

FIG. 8 is a partial sectional view illustrating another example of a pushing projection 14′ formed in the inserting groove 12. The pushing projection 14′ as illustrated in FIG. 8 is formed to have an inclined surface in a portion with which the head 62 of the hook 60 is in contact. Accordingly, when the head 62 of the hook 60 pushes on the inclined surface of the pushing projection 14′, the tablet computer 10 receives an upward force so that the tablet computer 10 can easily be separated from the connection apparatus 30.

In order to prevent the head 62 of the hook 60 from interfering with the pushing projection 14 when the hook 60 is inserted into the inserting groove 12, a distance A from a front end of the catch projection 13 to the side surface 12b of the inserting groove 12 is formed to be larger than a size of a width B of the hook 60 (see FIG. 7A). In other words, a distance D between an end of the pushing projection 14 and the head 62 of the hook 60 is formed to be larger than a distance C the hook 60 travels to engage with the catch projection 13 (see FIG. 7B). Here, the width B of the hook 60 refers to a width of a portion to correspond to an entrance of the inserting groove 12 when the hook 60 is completely inserted in the inserting groove 12 as illustrated in FIG. 7B.

With reference to FIGS. 9A and 9B, the connector groove 15 is formed so that the male connector 35 provided in the connection apparatus 30 can be inserted into the connector groove 15. The plurality of contact points 16 is provided on the bottom surface of the connector groove 15.

A front surface of the keyboard unit 20 includes a keyboard 22 and a touch pad 24, both of which may be used to enter data into the tablet computer 10. The connection apparatus 30 is disposed in the side surface the keyboard unit 20.

The peripheral apparatus 20 may be referred to as a keyboard unit. The peripheral apparatus 20 may be connected to the tablet computer 10 in order to improve the usability of the tablet computer 10. In addition to the keyboard unit, the peripheral apparatus 20 may be, for example, at least one of a stand to erect the tablet computer 10 at a certain angle to the floor and/or an auxiliary battery unit to supply electric power to the tablet computer 10. A structure to connect the tablet computer 10 to a connection apparatus 30 disposed in the peripheral apparatus 20 is the same as or similar to the structure to connect the tablet computer 10 to the connection apparatus 30 of the keyboard unit 20, therefore drawings and detailed descriptions thereof will be omitted.

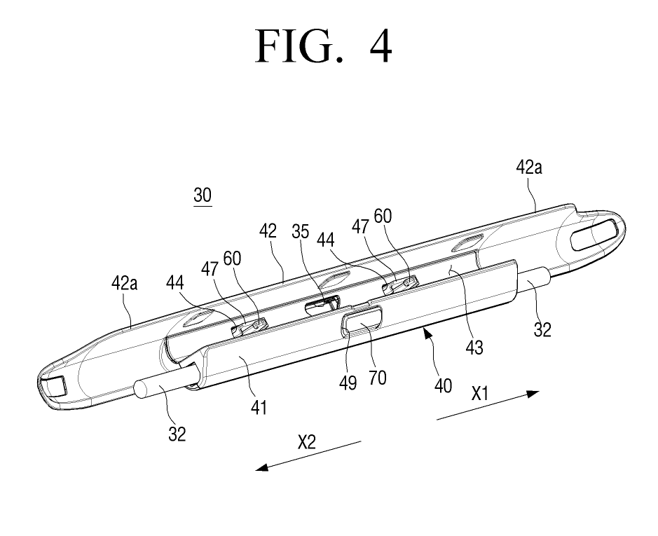

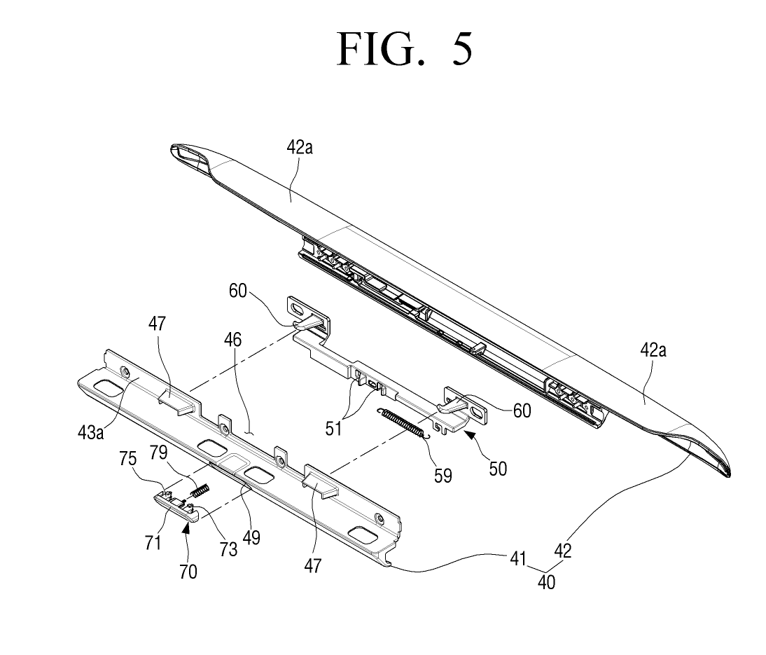

FIG. 4 is a perspective view illustrating a connection apparatus 30 used in a detachable electronic device 1 according to an exemplary embodiment of the present general inventive concept, and FIG. 5 is an exploded perspective view illustrating the connection apparatus 30 of FIG. 4.

Referring to FIGS. 3, 4, and 5, the connection apparatus 30 may include a base 40, a moving member 50, and a release button 70.

In this exemplary embodiment of the present general inventive concept, the base 40 is rotatably disposed in a side surface of the keyboard unit 20. For this, a rotation shaft 32 is provided at each of opposite ends of the base 40. The rotation shaft 32 is coupled to a hinge hole (not illustrated) provided in the keyboard unit 20. The rotation shaft 32 allows the base 30 to rotate with respect to the peripheral device 20, allowing the tablet computer 10 to be rotated with respect to the peripheral device 20. In the case of a keyboard being used as the peripheral device 20, the tablet computer 10 may be rotated to cover the keyboard 20, as illustrated for example in FIG. 3, for easy transport of the detachable electronic device 1 without separating the tablet computer 10 from the peripheral device 20.

The base 40 may approximately be formed in a rectangular parallelepiped shape. A mounting groove 43 is formed in the base 40 in parallel to the rotation shaft 32. The mounting groove 43 is formed so that a side of the tablet computer 10 can be inserted in the mounting groove 43. The hooks 60 and connector 35 are formed to project upwardly on the bottom surface of the mounting groove 43.

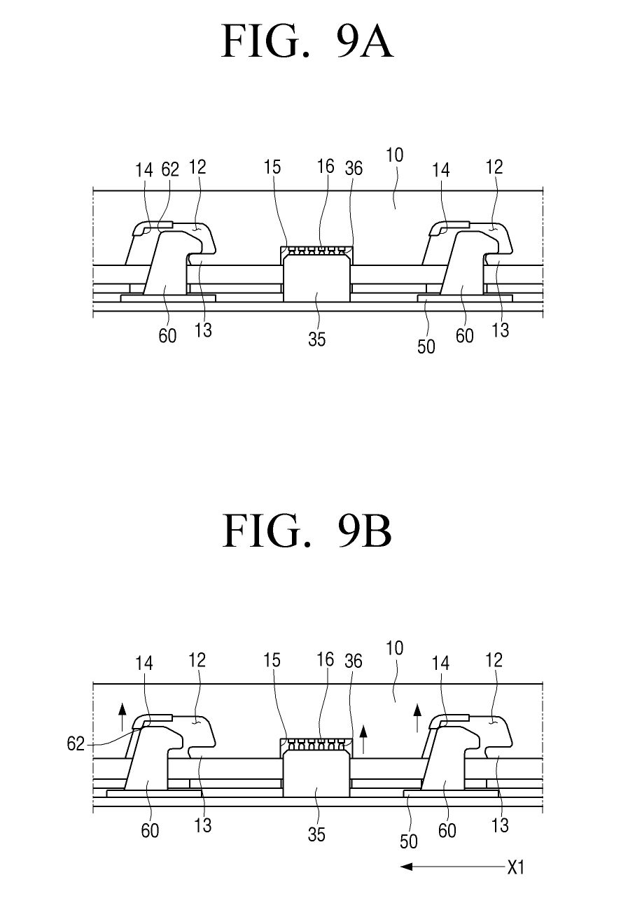

Referring to FIGS. 4 and 5, a side surface of the mounting groove 43 is extended so that two wings 42a elongated from opposite ends of the base 40 correspond to the side length of the tablet computer 10. If the side surface 42a of the mounting groove 43 is elongated as described above, the mounting groove 43 may stably support the tablet computer 10, and the aesthetic may be improved when the tablet computer 10 is connected to the connection apparatus 30 as illustrated in FIG. 3. However, the side surface 42a of the mounting groove 43 may not be extended as illustrated in FIG. 10.

The base 40 may be formed as an upper base 41 and a lower base 42 that can be detachable from each other. The rotation shaft 32 is disposed at each of the opposite ends of the upper base 41, and a button hole 49 in which the release button 70 is disposed is provided on the middle of the upper base 41. The bottom surface 43a of the mounting groove 43 is extended from the upper base 41. An opening 46 through which the connector 35 disposed in the lower base 42 can project is provided in the middle of the bottom surface 43a. Also, two through holes 44 through which the hooks 60 of the moving member 50 can project are formed on both sides of the opening 46 in the middle of the bottom surface 43a. A protection protrusion 47 to prevent the hook 60 from being damaged may be formed around each of the through holes 44.

The lower base 42 is assembled at a lower side of the upper base 41 to form the base 40. The moving member 50 is slidably assembled between the upper base 41 and the lower base 42. Accordingly, after the upper base 41, the moving member 50, and the lower base 42 are assembled, the moving member 50 can slidably move between the lower base 42 and the upper base 41 by a certain distance back and forth in a direction of the rotation shaft 32 of the base 40, that is, back and forth in a lengthwise direction of the base 40 (a direction of arrows X1 and X2).

The moving member 50 is disposed to move with respect to the base 40 by a certain distance back and forth in the lengthwise direction of the base 40. In detail, the moving member 50 is disposed to slidably move parallel to the mounting groove 43 below the bottom surface 43a of the mounting groove 43 of the base 40, that is, in the inside of the base 40. The moving member 50 may include a pressure member 59 to push the moving member 50 so that the moving member 50 receives a force in a predetermined direction and can be restored to an original position. One end of the pressure member 59 is fixed to the moving member 50, and the other end of the pressure member 59 is fixed to the base 40. A coil spring may be used as the pressure member 59.

Also, the hooks 60 and slope projections 51 are provided on the front surface of the moving member 50. Each hook 60 is coupled to an inserting groove 12 of the tablet computer 10, and two hooks 60 are disposed in a straight line on the front surface of the moving member 50.

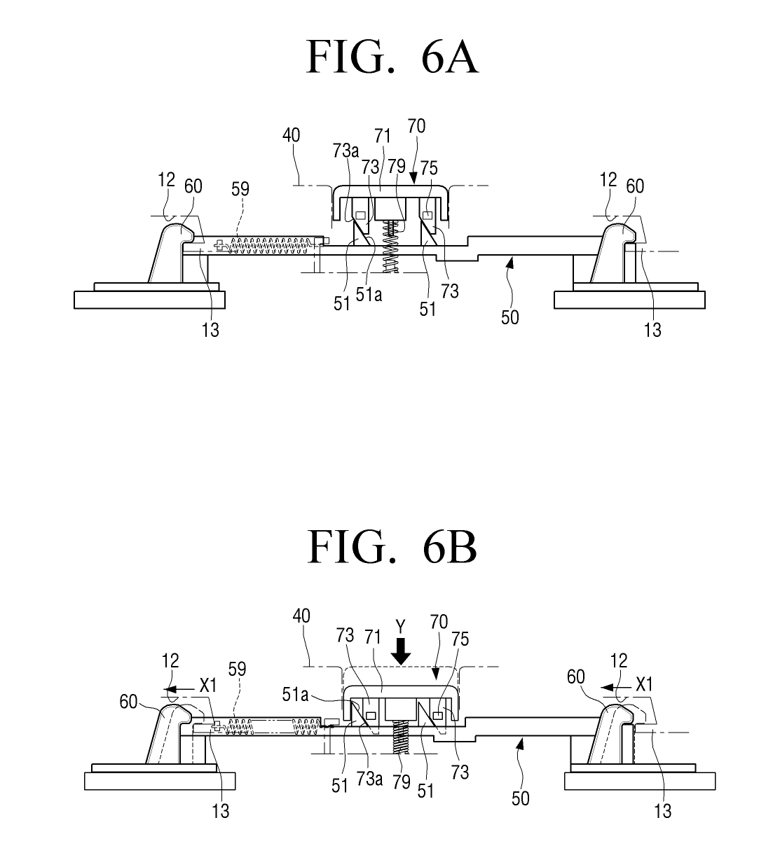

Referring to FIGS. 7A, 7B, and 7C, each hook 60 includes a head 62 that will be inserted into the inserting groove 12 of the tablet computer 10 and a nose 61 that will be caught by the catch projection 13 of the inserting groove 12. The nose 61 of the hook 60 projects a certain height C from the body of the hook 60. As illustrated in FIGS. 6A and 6B, the two hooks 60 are formed so that the noses 61 thereof face the same direction. The distance C between the hook 60 and the catch projection 13 of the inserting groove 12 corresponds to the height of the nose 61 of the hook 60. The head 62 of the hook 60 is formed to interfere with the pushing projection 14 formed in the inserting groove 12 of the tablet computer 10 and to push the pushing projection 14 in the upward direction. In the present exemplary embodiment, the head 62 of the hook 60 that is in contact with the pushing projection 14 of the inserting groove 12 is formed in an arc shape. Alternatively, the head 62 of the hook 60 may be formed as an inclined surface.

The slope projections 51 convert vertical movement of the release button 70 into horizontal movement, and are formed to be spaced apart a predetermined distance from each other between the two hooks 60 of the moving member 50. In the exemplary embodiment of the present general inventive concept illustrated in FIG. 5, the slope projections 51 are spaced apart a predetermined distance downwardly from the straight line connecting the two hooks 60 so as not to interfere with the connector 35 positioned between the two hooks 60.

The slope projection 51 may be formed in a triangle cross-sectional shape as illustrated in FIGS. 6A and 6B. Two slope projections 51 may be formed so that the vertical movement of the release button 70 is stably converted into the horizontal movement of the moving member 50. A slope surface 51a of the slope projection 51 may be formed in a slope to correspond to an inclined surface 73a of a pressure projection 73 of the release button 70.

As illustrated in the exemplary embodiment of FIGS. 6A and 6B, pressing the release button 70 moves the hook 60 to separate the tablet computer 10 from the connection apparatus 30, and the release button 70 is disposed to move with respect to the button hole 49 of the base 40. In other words, the release button 70 can move up and down in a vertical direction (a direction of arrow Y) with respect to a lengthwise direction of the base 40 (a direction of arrow X1).

As illustrated in FIGS. 5, 6A, and 6B, the release button 70 includes a button portion 71 and pressure protrusions 73. The button portion 71 to which a user applies a force is formed in a shape to correspond to the button hole 49 of the base 40. A stopper 75 to prevent the release button 70 from coming out of the button hole 49 of the base 40 is provided on a side surface of the button portion 71. Two pressure protrusions 73 are formed on a position corresponding to the two slope projections 51 of the moving member 50 on the bottom surface of the button portion 71. The pressure protrusion 73 has an inclined surface 73a to correspond to the slope surface 51a of the slope projection 51 of the moving member 50. Accordingly, when the release button 70 is pressed by a user, the inclined surfaces 73a of the pressure protrusions 73 are in contact with the slope surfaces 51a of the slope projections 51 to move the moving member 50 in the lengthwise direction of the base 40. The stopper 75 to prevent the release button 70 from coming out of the button hole 49 of the base 40 is provided on a side surface of the pressure protrusion 73. When the pressure protrusions 73 of the release button 70 press the slope projections 51 of the moving member 50, the moving member 50 is moved in the horizontal direction so that the heads 62 of the hooks 60 can push the pushing projection 14 of the inserting groove 12 upwardly.

Also, an elastic member 79 is disposed between the bottom surface of the release button 70 and the base 40. Accordingly, when the user presses the button portion 71, the elastic member 79 is pushed so that the release button 70 is moved downwardly, and when the user releases the user's finger from the button portion 71, the release button 70 is restored to the its original position by the elastic member 79.

As illustrated for example in FIGS. 9A and 9B, the connector 35 is disposed between the two hooks 60 on the bottom surface of the mounting groove 43 of the base 40. The connector 35 electrically connects the tablet computer 10 and the peripheral apparatus 20. The connector 35 may include a plurality of pogo pins 36. Each pogo pin 36 has an elastic member disposed in a lower end of the pogo pin 36, and has a structure that when a top of the pogo pin 36 is pushed by a downward force, the pogo pin 36 is pressed down a certain distance, and when the force is removed from the top thereof, the pogo pin 36 rises to return to the original position. The plurality of contact points 16 to correspond to the plurality of pogo pins 36 of the connector 35 are provided on the bottom surface of the connector groove 15 of the tablet computer 10 in which the connector 35 is inserted. Accordingly, when the tablet computer 10 is inserted into the mounting groove 43 of the base 40, the connector 35 is inserted into the connector groove 15 of the tablet computer 10, and thus the plurality of pogo pins 36 of the connector 35 comes in contact with the plurality of contact points 16 of the connector groove 15. As a result, electrical connection between the tablet computer 10 and the peripheral apparatus 20 is completed.

Also, because the exemplary embodiments of the present general inventive concept use the connector 35 including the pogo pins 36, when the hook 60 is released from the catch projection 13 of the tablet computer 10 by the release button 70, the tablet computer 10 receives force in an upward direction by the plurality of pogo pins 36 so that separation of the tablet computer 10 may be easy.

In the above description, the connector 35 with the pogo pins 36 was described. However, the connector 35 may use a connector 35′ with fixed pins rather than the pogo pins 36, as illustrated in FIG. 10. In this case, since the fixed pins of the connector 35′ cannot push up the tablet computer 10 like the pogo pins 36, at least one auxiliary pressure member 80 may additionally be disposed in a connection apparatus 30′. FIG. 10 illustrates a case in which two auxiliary pressure members 80 are disposed on the bottom surface of the mounting groove 43 in both sides of the two hooks 60 as another exemplary embodiment of a connection apparatus 30′ according to the present general inventive concept. As still another exemplary embodiment of the present general inventive concept, the auxiliary pressure member 80 may additionally be disposed in the base 40 even if the tablet computer 10 is too heavy to be pushed up by the plurality of pogo pins 36.

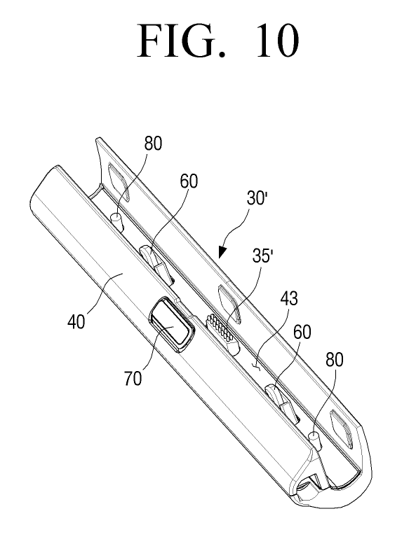

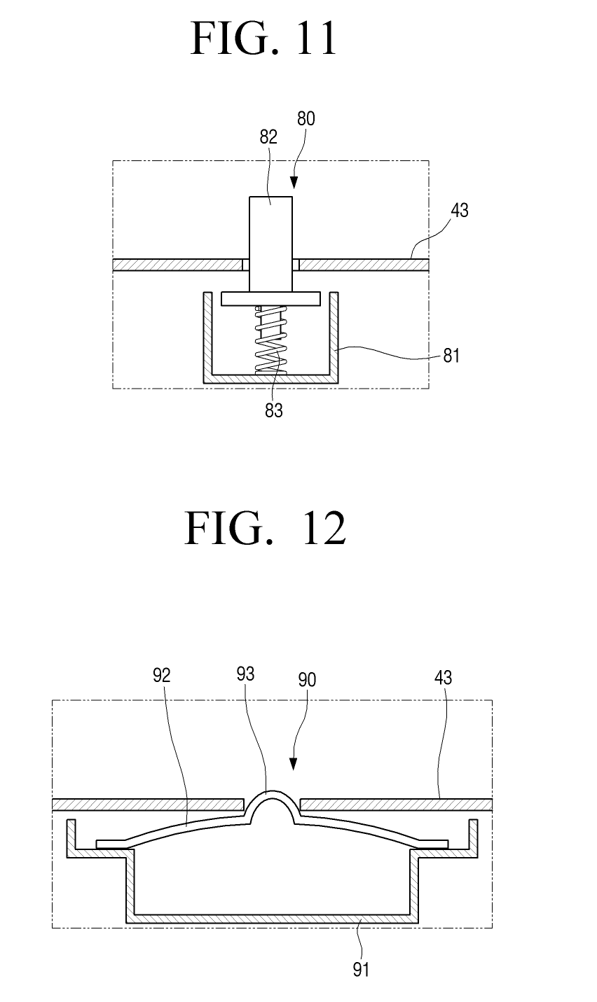

FIGS. 11 and 12 illustrate examples of auxiliary pressure members 80 and 90 that may be disposed in the connection apparatus 30′ according to an exemplary embodiment of the present general inventive concept.

FIG. 11 illustrates the auxiliary pressure member 80 using a compression coil spring as an elastic member 83. In other words, the auxiliary pressure member 80 as illustrated in FIG. 11 includes a supporting member 81, a pressurizing rod 82, and the elastic member 83 to push the pressurizing rod 82 in an upward direction. Accordingly, when the tablet computer 10 is mounted into the mounting groove 43 of the connection apparatus 30′, the pressurizing rod 82 is pushed by the tablet computer 10. After that, when the hook 60 is released from the catch projection 13 by the release button 70, the pressurizing rod 82 being supported by the elastic member 83 pushes the tablet computer 10 in an upward direction so that the tablet computer 10 may easily be separated from the mounting groove 43 of the connection apparatus 30′.

FIG. 12 illustrates the auxiliary pressure member 90 using a leaf spring as an elastic member 92 mounted on a supporting member 91, instead of the pressurizing rod 82, the compression coil spring 83, and the supporting member 81 illustrated in FIG. 11. According to the exemplary embodiment of the present general inventive concept illustrated in FIG. 12, the tablet computer 10 is mounted in the mounting groove 43 of the connection apparatus 30′, the side surface of the tablet computer 10 pushes a projection part 93 of the leaf spring 92 so that the leaf spring 92 is compressed. After that, when the release button 70 is pressed, and thus the hook 60 is released from the catch projection 13 of the inserting groove 12, the projection part 93 of the leaf spring 92 pushes the tablet computer 10 in an upward direction so that the tablet computer 10 may easily be separated from the mounting groove 43 of the connection apparatus 30′.

Hereinafter, processes of mounting and separating the tablet computer 10 to and from the connection apparatus 30 of the detachable electronic device 1 will be explained in detail with reference to accompanying drawings.

First, a process of mounting the tablet computer 10 illustrated in FIG. 1 to the connection apparatus 30 of the peripheral apparatus 20 (corresponding to the keyboard unit) will be explained.

A side surface of the tablet computer 10, that is, the side surface of the tablet computer 10 in which the inserting grooves 12 and the connector groove 15 are formed, is inserted into the mounting groove 43 of the connection apparatus 30. This causes the hooks 60 to be inserted into the inserting grooves 12, and the connector 35 to be inserted into the connector grooved 15. As a result, the tablet computer 10 is connected to the keyboard unit 20 as illustrated in FIG. 2.

Hereinafter, a process by which the tablet computer 10 is fixed to the mounting groove 43 by the hooks 60 of the connection apparatus 30 will be explained in detail with reference to FIGS. 5, 7A, and 7B.

If the inserting groove 12 of the tablet computer 10 is aligned with the hook 60 of the connection apparatus 30, the hook 60 is moved in a direction of arrow X1 by the catch projection 13, and thus becomes a state as illustrated in FIG. 7A. The tablet computer 10 may move downward due to its own weight, or may be pushed downward by an external force such as from a user of the tablet. When the tablet computer 10 is moved downward in this fashion, the nose 61 of the hook 60 comes out of the front end of the catch projection 13, the moving member 50 is moved in a direction of arrow X2 by the pressure member 59 disposed in the base 40 (as illustrated in FIG. 5) so that the nose 61 of the hook 60 engages the catch projection 13 of the inserting groove 12 as illustrated in FIG. 7B. In other words, the tablet computer 10 is connected to the keyboard unit 20 by the weight of the tablet computer 10 or an external downward force, as well as by the restoring force of the pressure member 59.

FIG. 9A illustrates a state in which the two hooks 60 and connector 35 of the connection apparatus 30 are connected to the two inserting grooves 12 and connector groove 15 of the tablet computer 10. As described above, after the nose 61 of the hook 60 of the connection apparatus 30 is caught to the catch projection 13 of the inserting groove 12, the tablet computer 10 is fixed to the keyboard unit 20, and thus is not separated, and the tablet computer 10 and the keyboard unit 20 are electrically connected to each other through the connector 35.

Hereinafter, a process of separating the tablet computer 10 connected to the connection apparatus 30 of the keyboard unit 20 will be explained in detail with reference to FIGS. 6A and 6B.

FIG. 6A is a sectional view schematically illustrating a relationship between the release button 70, the moving member 50, and the hooks 60 before the release button 70 is pressed according to an exemplary embodiment of the present general inventive concept. FIG. 6B is a sectional view schematically illustrating relationship between the release button 70, the moving member 50, and the hooks 60 when the release button 70 is pressed according to an exemplary embodiment of the present general inventive concept. In FIGS. 6A and 6B, in order to clearly explain the movement of the release button 70, hooks 60, and moving member 50 relative to the base 40, some portions of the base 40 around the release button 70, hooks 60, and moving member 50, as well as changed positions of these elements, are illustrated by dotted lines.

When the tablet computer 10 is connected to the connection apparatus 30 of the keyboard unit 20 as illustrated in FIG. 2, the release button 70 is positioned on the same plane as that of the base 40 as illustrated in FIG. 6A.

In this state, when the user wants to separate the tablet computer 10, the user presses the release button 70. When the user presses the release button 70, as illustrated in FIG. 6B, the button portion 71 is moved downwardly, and thus, the pressure protrusions 73 formed on the bottom surface of the button portion 71 are moved downwardly to push on the slope projections 51 of the moving member 50.

When the pressure protrusions 73 of the release button 70 push on the slope projections 51 of the moving member 50, the moving member 50 is moved in a direction (a direction of arrow X1) perpendicular to the moving direction (a direction of arrow Y) of the release button 70, that is, in the lengthwise direction of the base 40.

When the moving member 50 moves in the X1 direction, the hooks 60 formed on the front surface of the moving member 50 also moves in the X1 direction. When the hook 60 moves in the X1 direction, as illustrated in FIG. 9B, the nose 61 of the hook 60 is released from the catch projection 13 of the inserting groove 12 and the head 62 of the hook 60 is in contact with the pushing projection 14 of the inserting groove 12 to push on the pushing projection 14 upwardly. At this time, the plurality of pogo pins 36 of the connector 35 also pushes the tablet computer 10 upward. Here, FIG. 9B is a partially sectional view conceptually illustrating a state in which the tablet computer 10 is pushed upwards by the hooks 60 and the pogo pins 36 of the connector 35 when the hooks 60 are moved by the release button 70. As a result, the user may easily separate the tablet computer 10 from the connection apparatus 30 of the keyboard unit 20.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A detachable electronic device comprising:
a connection apparatus that is disposed in one end of a peripheral apparatus and to which a tablet computer is detachably mounted;
wherein:
the connection apparatus comprises:
a base disposed in the peripheral apparatus;
a mounting groove that is formed in the base and in which one end of the tablet computer is inserted;
a hook disposed on a bottom surface of the mounting groove and adapted to move parallel to the mounting groove; and
a pressure member to push the hook in a first direction, and
wherein:
the tablet computer comprises:
an inserting groove that is formed in the one end of the tablet computer and in which the hook can be inserted;
a catch projection that is formed at a side surface of the inserting groove and which engages with the hook; and
a pushing projection disposed opposite to the catch projection inside the inserting groove.

2. The detachable electronic device of claim 1, wherein:
a distance between the pushing projection and a head of the hook is larger than a distance traveled by the hook to engage with the catch projection.

3. The detachable electronic device of claim 1, wherein:
when the hook moves more than the distance between the hook and the catch projection in a second direction opposite to the first direction, the hook pushes the pushing projection away from the mounting groove.

4. The detachable electronic device of claim 1, wherein:
the connection apparatus further comprises:
a moving member on which the hook is formed, the moving member being disposed to move with respect to the base;
a slope projection formed on the moving member;
a release button that is disposed in the base to move perpendicular to the moving member and comprises a pressure protrusion to push on the slope projection; and
an elastic member disposed between the release button and the moving member, and
wherein:
when the release button is pressed, the pressure protrusion of the release button pushes on the slope projection of the moving member, and thus the moving member is moved so that the hook pushes the pushing projection away from the mounting groove.

5. The detachable electronic device of claim 1, wherein:
the connection apparatus comprises a protection protrusion to surround the hook formed on the bottom surface of the mounting groove.

6. The detachable electronic device of claim 1, wherein:
the base is rotatably disposed in the peripheral apparatus.

7. The detachable electronic device of claim 1, wherein:
the connection apparatus comprises a connector to electrically connect the tablet computer and the peripheral apparatus disposed on the bottom surface of the mounting groove.

8. The detachable electronic device of claim 7, wherein:
the connector comprises a plurality of pogo pins.

9. The detachable electronic device of claim 1, wherein:
the connection apparatus comprises an auxiliary pressure member formed on the bottom surface of the mounting groove to push the tablet computer away from the mounting groove.

10. The detachable electronic device of claim 1, wherein:
the peripheral apparatus comprises at least one of a keyboard unit, a stand, and an auxiliary battery unit.

11. A connection apparatus to connect a peripheral apparatus and a tablet computer, the connection apparatus comprising:
a base rotatably disposed in one end of the peripheral apparatus;
a mounting groove that is formed in the base and in which one end of the tablet computer is inserted;
a moving member disposed below a bottom surface of the mounting groove to move parallel to the mounting groove;
a hook that is formed on a top surface of the moving member and projects inside the mounting groove through a through hole of the mounting groove;
a pressure member with one end fixed to the moving member and the other end fixed to the base to push the moving member in a predetermined direction;
a slope projection formed on a top surface of the moving member;
a release button that is disposed in the base to move perpendicular to the moving member and comprises a pressure protrusion to push on the slope projection; and
an elastic member disposed between the release button and the moving member,
wherein when the release button is pressed, the pressure protrusion of the release button pushes on the slope projection of the moving member, and thus the moving member is moved in a direction opposite to the predetermined direction in which the pressure member pushes the moving member.

12. The connection apparatus of claim 11, wherein:
when a force applied to the release button is removed, the moving member is restored to an original position by the pressure member.

13. The connection apparatus of claim 11, wherein:
the base comprises a upper base and a lower base;
the moving member is disposed to move between the upper base and the lower base; and
the upper base comprises a button hole in which the release button is disposed.

14. The connection apparatus of claim 11, wherein:
a protection protrusion to surround the hook is formed on the bottom surface of the mounting groove.

15. The connection apparatus of claim 11, wherein:
when the release button is pressed, the hook is formed to push the tablet computer away from the mounting groove.

16. The connection apparatus of claim 11, further comprising:
rotation shafts disposed opposite ends of the base.

17. The connection apparatus of claim 11, wherein:
a connector to electrically connect the tablet computer and the peripheral apparatus is disposed in the bottom surface of the mounting groove.

18. The connection apparatus of claim 17, wherein:
the connector comprises a plurality of pogo pins.

19. The connection apparatus of claim 11, wherein:
at least one auxiliary pressure member to push the tablet computer away from the mounting groove is disposed in the bottom surface of the mounting groove.
